(19) United States
(12) Patent Application Publication
(10) Pub. No.: US 2026/0068770 A1
(43) Pub. Date: Mar. 5, 2026

(54) OPTOELECTRICAL CROSSBAR SWITCH

(71) Applicant: MIXX TECHNOLOGIES, INC., San Jose, CA (US)

(72) Inventors: Rebecca Kayla Schaevitz, Sunnyvale, CA (US); Vivek Raghuraman, San Jose, CA (US)

(73) Assignee: MIXX TECHNOLOGIES, INC., San Jose, CA (US)

(21) Appl. No.: 19/315,358

(22) Filed: Aug. 29, 2025

Related U.S. Application Data
(60) Provisional application No. 63/689,555, filed on Aug. 30, 2024.

(51) Int. Cl. H01L 25/16; G02B 6/122

(52) U.S. Cl. CPC H10W 90/00; G02B 6/122

(57) ABSTRACT

An optoelectrical package may include at least one electrical switch application-specific integrated circuit (ASIC) and at least one optical engine. The electrical ASIC may be disposed at a central portion of a communication interface. The electrical ASIC may incorporate a crossbar functionality. The optical engine may be arranged relative to the communication interface. The optical engine may be electrically connected to the at least one electrical ASIC. The optical engine may be disposed adjacent to the at least one electrical ASIC. The optical engine may include a fiber connector for one or more fibers, a photonic integrated circuit, and an electronic integrated circuit. The optical engine may be configured to convert an optical signal obtained from the fiber connector to an electrical signal for use by the electrical ASIC and vice versa.

### CROSS REFERENCE TO RELATED APPLICATIONS

This U.S. Patent Application claims priority to U.S. Provisional Patent Application No. 63/689,555, titled “OPTOELECTRICAL CROSSBAR SWITCH,” and filed on August 30, 2024, the disclosure of which is hereby incorporated by reference in its entirety.

### TECHNICAL FIELD

This disclosure generally relates to an optoelectrical crossbar switch, and additionally, to a system of interconnected xPUs, memory, or other ASIC using one or more optical engines and/or transceivers and one or more optoelectrical crossbar switches.

### BACKGROUND

Unless otherwise indicated herein, the materials described herein are not prior art to the claims in the present application and are not admitted to be prior art by inclusion in this section.

Artificial intelligence (AI), high-performance computing (HPC), or similar such systems rely on a significant amount of interconnected compute nodes (e.g. GPU, CPU, NPU, TPU, etc., now called “xPU”) and memory to enable large data processing for improved models, such as large language models (LLMs) and other such generative AI use cases. In order to interconnect the vast array of compute nodes, architectures may utilize a cascading series of network router switches. These network router switches may be packet-based and may lead to significant delay in transferring information. The more compute nodes needed, the more switches may be included and thus, the more delay that may be incurred. A common metric used in these systems is Model FLOPs Utilization (MFU) that may provide the percentage of time in compute vs. all else, such as time in networking. Many large model systems may have less than 30% MFU. To improve MFU, systems may be designed to reduce the time in network, enable better fail-over mechanisms, and/or improve reliability.

The subject matter claimed in the present disclosure is not limited to implementations that solve any disadvantages or that operate only in environments such as those described above. Rather, this background is only provided to illustrate one example technology area where some implementations described in the present disclosure may be practiced.

### SUMMARY

In an example, an optoelectrical package may include at least one electrical application-specific integrated circuit (ASIC) and at least one optical engine. The electrical ASIC may be disposed at a central portion of a communication interface. The electrical ASIC may incorporate a crossbar functionality. The optical engine may be arranged relative to the communication interface. The optical engine may be electrically connected to the at least one electrical ASIC. The optical engine may be disposed adjacent to the at least one electrical ASIC. The optical engine may include a fiber connector for one or more fibers, a photonic integrated circuit, and an electronic integrated circuit. The optical engine may be configured to convert an optical signal obtained from the fiber connector to an electrical signal for use by the electrical ASIC and vice versa.

In another example, an optoelectrical package may include at least one electrical application-specific integrated circuit (ASIC) and at least one optical engine. The electrical ASIC may be disposed at a central portion of an interposer. The electrical ASIC may incorporate a crossbar functionality. The optical engine may be integrated into the interposer. The optical engine may be electrically connected to the at least one electrical ASIC. The optical engine may be disposed adjacent to the at least one electrical ASIC. The optical engine may include a fiber connector for one or more fibers, a photonic integrated circuit, and an electronic integrated circuit. The optical engine may be configured to convert an optical signal obtained from the fiber connector to an electrical signal for use by the electrical ASIC and vice versa.

The objects and advantages of the examples will be realized and achieved at least by the elements, features, and combinations particularly pointed out in the claims.

Both the foregoing general description and the following detailed description are given as examples and are explanatory and not restrictive of the invention, as claimed.

### DESCRIPTION OF DRAWINGS

Example implementations will be described and explained with additional specificity and detail using the accompanying drawings in which:

FIG. 1 illustrates an example optoelectrical crossbar switch;

FIGS. 2A-2C illustrate different implementations of the optoelectrical crossbar switch of FIG. 1;

FIG. 3 illustrates an optoelectrical crossbar switch arranged in an architecture;

FIG. 4 illustrates an optoelectrical crossbar switch arranged in another architecture; and

FIG. 5 illustrates a control device that may be used to control operations associated with a system of optoelectrical crossbar switches.

### DETAILED DESCRIPTION

Crossbar switches may be network switching devices used to connect multiple inputs with multiple outputs in various (often a matrix) configurations. Crossbar switches may be a subset category of general switches, where general switches may include packet-based routers in addition to the crossbar switches, as described herein. In most instances, a crossbar switch may facilitate simultaneous connections without interference between the inputs and outputs. Some crossbar switches utilize re-timers and/or serializers/deserializers (SerDes). Further, some traditional crossbar switches may be fully optical crossbar switches for optical signals and some traditional crossbar switches may be fully electrical crossbar switches for electrical signals.

Challenges with a fully optical crossbar switch may include an insertion loss and/or polarization requirements. One example of a fully optical crossbar switch may be based on micro-electrical mechanical systems (MEMS)-based micromirrors that may redirect the light to an assigned port. In such an arrangement, the link between two ASICs may be limited to a mirror-based system, where the increased insertion loss may make it harder to close the link, which may result in higher power usage and/or lower system efficiencies. Alternatively, or additionally, the micromirrors may be relatively large and may be limited by the number of ports enabled by the micromirrors. For example, systems in application today may be limited to 144 total ports.

Another example of a fully optical crossbar switch that may solve a size problem would be using a photonic integrated circuit (PIC). Enabling a crossbar switch using a PIC may include polarizing light in a transverse-electric (TE) mode. For TE operation, light may be rotated and recombined within the PIC or externally controlled in TE mode via polarization maintaining (PM) fiber. PM fiber may be prohibitively expensive and may not likely be implemented. Rotating light in the PIC and creating the crossbar architecture may result in high (e.g., greater than 10dB) insertion loss. Since most optical links require less than 4dB losses between endpoints, the loss in the PIC must be offset by using optical amplifiers, which may add significantly to the power consumption, inefficiencies, and/or limiting the reach.

In another example of a fully optical crossbar switch, a piece of equipment may automate a patch panel with mechanical arms that may be programed to move fibers from one port to another. This method may be bulky and/or slow to change. None of the solutions for creating a fully optical crossbar switch gives the density, port count, reconfigurability, and/or power efficiency of the optoelectrical crossbar switch proposed in this disclosure.

Further, a fully electrical crossbar switch may enable various attributes, such as speed of reconfigurability, but may be limited by the number of SerDes disposed on the perimeter to achieve high port count and/or may use costly silicon capable of high speed operation. By utilizing an optical engine integrated with an electrical crossbar switch as described herein, improvements to the speed of reconfigurability may be obtained, by (1) increasing area available for SerDes through integration with the optical engine, which may also (2) reduce the cost of the core silicon for the crossbar switch as the core silicon can operate at lower speed, (3) ease packaging challenges that can then allow scaling to more chips on package and thus higher port counts, and/or (4) increase the reach from 3m of copper to at least 500m to enable a larger scale clusters with more xPUs and/or memory nodes. Alternatively, or additionally, compared to the fully optical switches which further deteriorate the link budget, the optoelectrical switch described herein may convert the optical domain to the electrical domain, then back to the optical domain again, which may restore the original signal quality and can then achieve the link distances dictated by standards, such as Institute of Electrical and Electronics Engineers (IEEE), at every connection point. The optical engine may not be sensitive to polarization of the incoming optical signal and thus, may not incur further link loss.

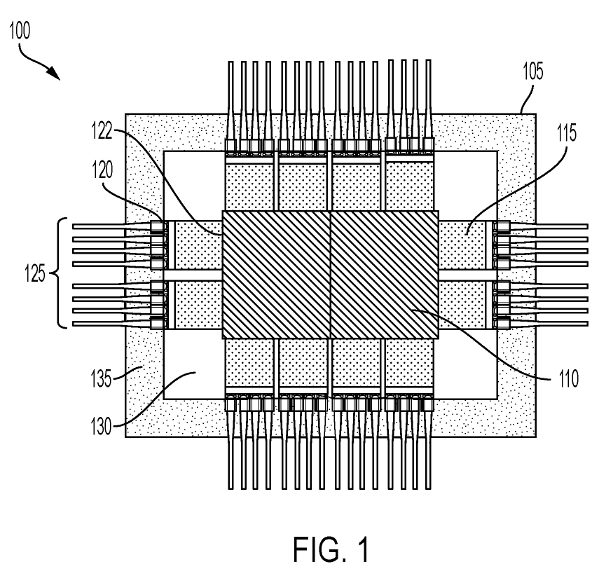

FIG. 1 illustrates an example optoelectrical crossbar switch 100 where electrical signals and optical signals may be converged in a single semiconductor, optoelectrical package 105 (also referred to as a “package” 105). To integrate these electrical and optical signals, a communication interface may be utilized, such as an interposer 130, or a substrate 135. In some instances, the optoelectrical crossbar switch 100 may include one or more electrical switch application-specific integrated circuits (ASICs) 110 disposed at a central portion of the interposer 130 and the package 105 may include optical engines 115 disposed adjacent and/or about the electrical ASICs 110 integrated with the interposer 130. In some instances, the optical engines 115 may be embedded in the interposer 130. Alternatively, or additionally, the optical engines 115 may be disposed on top of the interposer 130. Alternatively, or additionally, the optical engines 115 may be integrated onto the package 105. In some instances, the electrical ASICs 110, the optical engines 115, and/or the interposer 130 may be packaged using Chip-on-Wafer-on-Substrate (CoWoS) technology, such as CoWoS-S, CoWoS-L, and the like. As illustrated, the optoelectrical crossbar switch 100 may include two electrical ASICs 110, but may be scaled up to include more electrical ASICs 110 or scaled down to be a single electrical ASIC 110, which may be based on a client request for the optoelectrical crossbar switch 100, or a workload to be performed using the optoelectrical crossbar switch 100.

In some instances, the optical engines 115 may be operable to perform an electrical to optical conversion in the package 105. The optical engines 115 may include an electronic integrated circuit (EIC) and/or a photonic integrated circuit (PIC) and a fiber connector. In some instances, each of the optical engines 115 may be operable to support up to 64 links or more, where the links may be composable into various chunks. In some instances, the optical engines 115 may be composed into chunks based on utilization within a particular workflow, a request by a particular workflow, and/or to enable redundancy in view of a reliability requirement associated with the optoelectrical crossbar switch 100. In these and other instances, the optical engines 115 may include crossbar functionality enabled in the EIC, in the PIC, and/or in both the EIC and the PIC.

In instances in which the optical engines 115 are utilized with the interposer 130, the optical engines 115 may be operable to replace a silicon bridge within the interposer 130. In some instances, the optical engines 115 may include networking protocol translation. In such instances, the networking protocol translation may be enabled in the EIC. Additional details associated with the links of the optical engines and/or how the links in the optical engines may be composed is described herein.

The optical engines 115 may include a chip edge 120 for one or more optical fibers 125 and the optical engines 115 may be configured to convert optical signals obtained from the optical fibers 125 into electrical signals for use by the electrical ASICs 110, or vice versa. In some instances, the optical engines 115 may be a fraction of, or up to, a single full reticle edge 122, which may facilitate a connection of the optical fibers 125. For example, as illustrated, the optical engines 115 may have a reticle that is approximately half a standard reticle edge 122 and may support up to 160 connected optical fibers 125 or more of the optical fibers 125. In some instances, two optical engines 115 may span a full reticle edge 122 and may support up to 128 links, 160 links, and/or more links. The optical fibers 125 may be mateable and/or de-mateable relative to the optical engines 115, and the interposer 130 and/or the package 105 may be able to go through solder reflow, and/or may be able to go through wafer level processing.

In some instances, the optical engines 115 may be operable to support switching operations. For example, the optical engines 115 may each include an electronic integrated circuit (EIC) that may enable the electrical-to-optical conversion and vice versa, and may also enable composability of the links and perform switching relative to received and/or transmitted data. The switching between the connected devices may allow a configuration of the number of xPUs and/or memory or other ASIC included in a system without changing the physical network architecture of the optoelectrical crossbar switch 100.

In some instances, the optoelectrical crossbar switch 100, including the optical engines 115, may not use re-timers, which may enable the optoelectrical crossbar switch 100 to use up to 70% less power than traditional packet-based switches. Other improvements relative to traditional packet-based switches may include latency in the optoelectrical crossbar switch 100, which may be less than 500 nanosecond (ns) latency, whereas the traditional packet-based switches may have greater than 1 microsecond (µs) latency. Alternatively, or additionally, the integration of the optical engines 115 with the electrical ASICs 110 may enable a dense, low power, low area utilization, die-to-die (D2D) communication protocol. This D2D design may drive more links per reticle edge 122 compared to traditional electrical switches that use LR (long range) SerDes.

As illustrated in FIG. 1, the interposer 130 of the package 105 may be an example wafer-scale solution including electrical signal to optical signal conversion (and vice versa) and/or electrical switching in the package 105, such as by the optical engines 115 as described herein, or by the electrical ASICs 110. Alternatively, or additionally, surrounding the edge of the package 105 may be associated with optical input/output (IO). The optical IO may be based on particular requirements associated with connected devices (e.g., a customer proprietary solution), or the optical IO may be based on one or more optical standards, such as various IEEE optical standards (e.g., 100GBASE-DR). As such, the optical engine 115 can enable network protocol translation along with switching capabilities.

Some traditional switches (such as packet-based switches) may support up to 512 lanes in a given package. As described herein, the optoelectrical crossbar switch 100 may be scalable by including more electrical ASICs 110 and/or more optical engines 115. For example, as illustrated in FIG. 1, the optoelectrical crossbar switch 100 may support 768 links and/or may be additionally scaled, such as to 1024 links, by adding additional electrical ASICs 110 to the package 105, or by improving the density of the IO. In another example, the optoelectrical crossbar switch 100 may support more than 512 lanes and/or may support greater than or equal to 100 Gbps bandwidth per lane. The traditional packet-based switches may be unable to support such scalability by accommodating additional ASICs as the substrate would then need to support more electrical IO and thus fan out to more ball-grid arrays (BGAs). The size of the package may then lead to warpage and/or the thinness of the substrate, which may be required for high-speed signals, and/or may further degrade the structural integrity of the package. Alternatively, or additionally, the higher power and thermal impacts may lead to low reliability and/or failures in the field.

In some instances, the electrical high speed signals in the package 105 may be configured to be transmitted/received on the reticle edge 122 of the electrical ASICs 110 in the package 105, then converted to optical signals and transmitted as optical high speed signals via fibers (e.g., the optical fiber 125 connector attached to the optical engines 115 at the edge of the package 105). In such instances, the optical high speed signals may not pass through the substrate 135 (where the power, ground, and low speed signals may be present in the substrate 135). In such arrangement, the substrate 135 may be thicker (as the substrate 135 may no longer support high-speed signals) and thus, may support more electrical ASICs 110 and/or other dies, such as the optical engines 115, at the center thereof. The thickness of the substrate 135 may reduce the warping that may be experienced in fully electrical switches. Alternatively, or additionally, the package 105 may be less limited by the substrate 135 (e.g., an organic substrate) included therein, as the IO may be handled at the edge portion thereof, as opposed to through the substrate 135 in fully electrical switches (or any fully electrical ASIC package). In some instances, with more space available in the substrate 135, more vias may be used for degassing and/or thermal egress to enable a higher reliability in the package 105. Similar to the substrate 135, by integrating the optical engines 115 into or onto the interposer 130, the density of connectivity IOs may be reduced, which may allow the interposer 130 to be thicker with fewer vias, which may result in a more stable interface that can scale relative to traditional packet-based switches.

Alternatively, or additionally, the optoelectrical crossbar switch 100 and/or the optical engines 115 may be operable to support connected legacy devices, such as traditional transceivers. For example, components may be connected to the optoelectrical crossbar switch 100 via the optical fibers 125 and one or more optical transceivers such that communications may occur between the components (e.g., memory, switch ASICs, xPUs, network interface cards (NICs), etc.) and the optoelectrical crossbar switch 100. By connecting the optoelectrical crossbar switch 100 to legacy components, the radix of the system can increase, contributing to the improvements described herein.

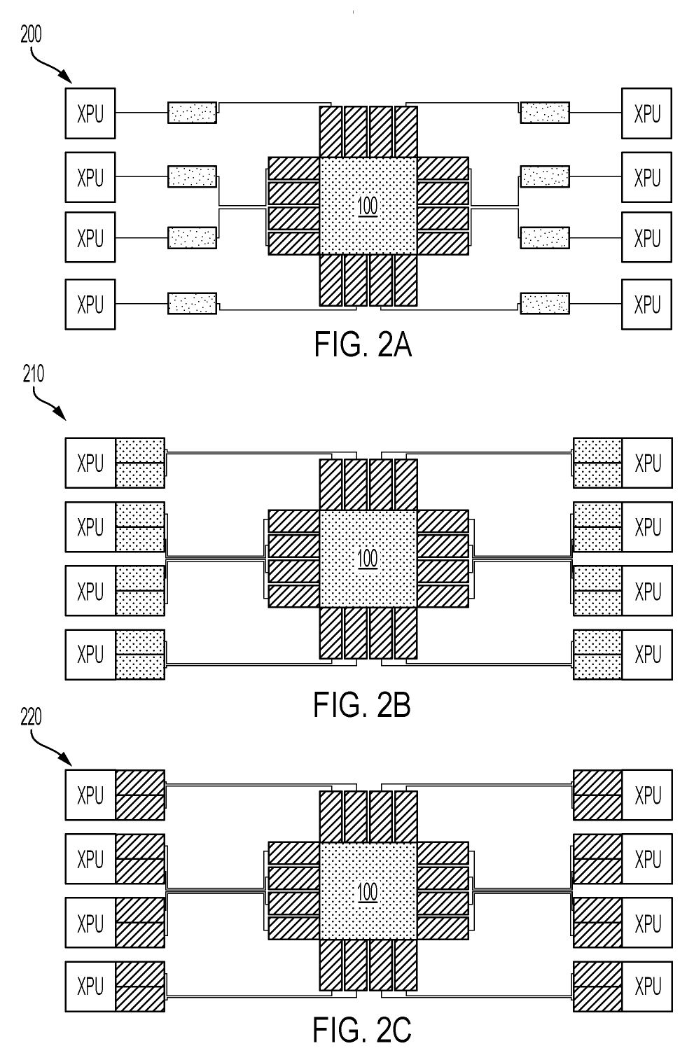

FIGS. 2A-2C illustrate a first implementation 200, a second implementation 210, and a third implementation 220, respectively, in which the optoelectrical crossbar switch 100 of FIG. 1 may be used. In FIG. 2A, the first implementation 200 illustrates that the optoelectrical crossbar switch and/or the optical engines may be interoperable with standards-defined transceivers that may be single wavelength and/or multi-wavelength, where the transceivers may be pluggable and/or connected to the other side of the optical link (the other side of the optical link referring to an end opposite the optical engines). For example, the single wavelength may include IEEE 200GBASE-DR1 or DR4 and the multi-wavelength may include IEEE 800GBASE-FR4 or FR8. Alternatively, or additionally, a transceiver equivalent may be connected to the other side of the optical link, which may include proprietary transceiver-like devices.

In FIG. 2B, the second implementation 210 illustrates the optoelectrical crossbar switch optically coupled with an integrated transceiver, or integrated transceiver equivalent (e.g., an optical engine or co-packaged optics or integrated optical engine) on the other side of the optical link. The integrated transceiver or integrated transceiver equivalent may be embedded in a similar package with another ASIC, such as an xPU or another crossbar switch.

In FIG. 2C, the third implementation 220 illustrates the optoelectrical crossbar switch and/or the optical engines optically coupled with other optical engines on the other side of the optical link. In such scenarios, the other optical engines may include an EIC that may facilitate switching capabilities in addition to supporting the electrical-to-optical conversion, such that the third implementation may include redundancies, improved reliability, and/or additional reconfigurability benefits.

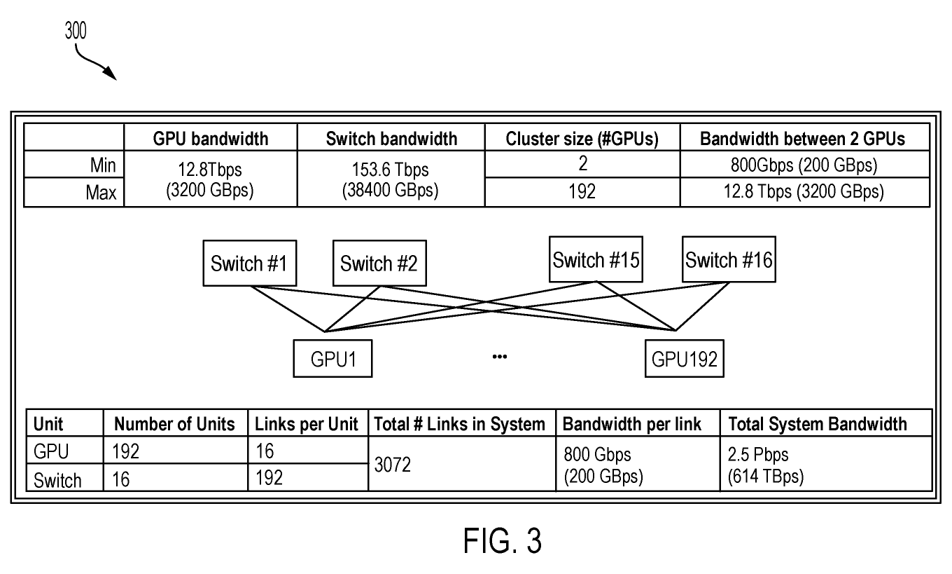

FIG. 3 illustrates multiple optoelectrical crossbar switches (each labeled as “Switch” in FIG. 3) arranged in an architecture 300 to support inference applications. Alternatively, or additionally, FIG. 3 illustrates scaling that may be performed with multiple optoelectrical crossbar switches, where the scaling may be performed based on a workload or other demands on the system.

In some instances, multiple optoelectrical crossbar switches may be used to link multiple xPUs together to scale a system, as illustrated up to 192 xPUs at 800 Gbps per direction speed (GPUs illustrated in FIG. 3) may be connected to one another using a number of the optoelectrical crossbar switches, which may differ based on the IO capacity of the xPUs. Other implementations could be enabled with up to 768 xPUs with 200 Gbps speed. Further scaling to higher GPUs or bandwidth per link can be enabled. An example and as illustrated, each GPU may have a total of 16 links of 800 Gbps connecting each link to a different switch. With 192 GPUs and 16 switches, the system can enable all-to-all connectivity of 800 Gbps per link across all 192 GPUs, could scale to two GPUs connected fully together with 12.8 Tbps bandwidth, or any combination between. This bandwidth is just an example that can scale to more radix or more bandwidth per lane in other configurations. In an example, to physically connect the system in instances in which two racks are used, 96 XPUs may be included per rack with eight optoelectrical crossbar switches included per rack. In instances in which four racks are used, 48 XPUs may be included per rack with four optoelectrical crossbar switches included per rack. In either illustrated implementation (and/or in other implementations not illustrated), the optoelectrical crossbar switches may allow the system to have less than or equal to 500 ns latency, which may be an improvement over traditional packet-based switches that connect up to 72 xPUs and may have at least 1 µs latency and 400 Gbps maximum bandwidth. Conversely, for an equivalent sub 500 ns latency, 8 xPUs may be connected in an all-electrical configuration. Consequently, using the optoelectrical crossbar switch, the system can improve by up to 48 times in compute capacity with similar link bandwidth, or up to 24 times in compute capacity with two times the link bandwidth.

In some instances, the architecture 300 may depend on the device on the other side of the optical link, which may allow various configurations of the optoelectrical crossbar switches and/or connected xPUs. For example, in some instances, the components may be arranged such that an optical engine may be connected to each xPU in the system. In other instances, a traditional transceiver may be connected to each xPU in the system. Depending on the type of device the xPUs may be connected to, the system may scale more or less. For example, in instances in which a transceiver (or transceiver-like proprietary component) may be used, the cluster size may vary from 2 to 768 xPUs and the bandwidth between the xPUs may vary between 200 Gbps to 12.8 Tbps, based on the number of xPUs in the cluster. A cluster may refer to a low-latency link between xPUs that may be operable to support parallel processing capabilities utilized by large AI models. In instances in which the xPU is connected to another optoelectrical crossbar switch, the cluster size may vary from 2 to 768 xPUs while the bandwidth between the xPUs may vary between 800 Gbps to 51.2 Tbps, based on the number of xPUs in the cluster, and where the number of optoelectrical crossbar switches in the system may be increased to support the additional links (e.g., up to four times the number of optoelectrical crossbar switch in the transceiver-based architecture) in these examples.

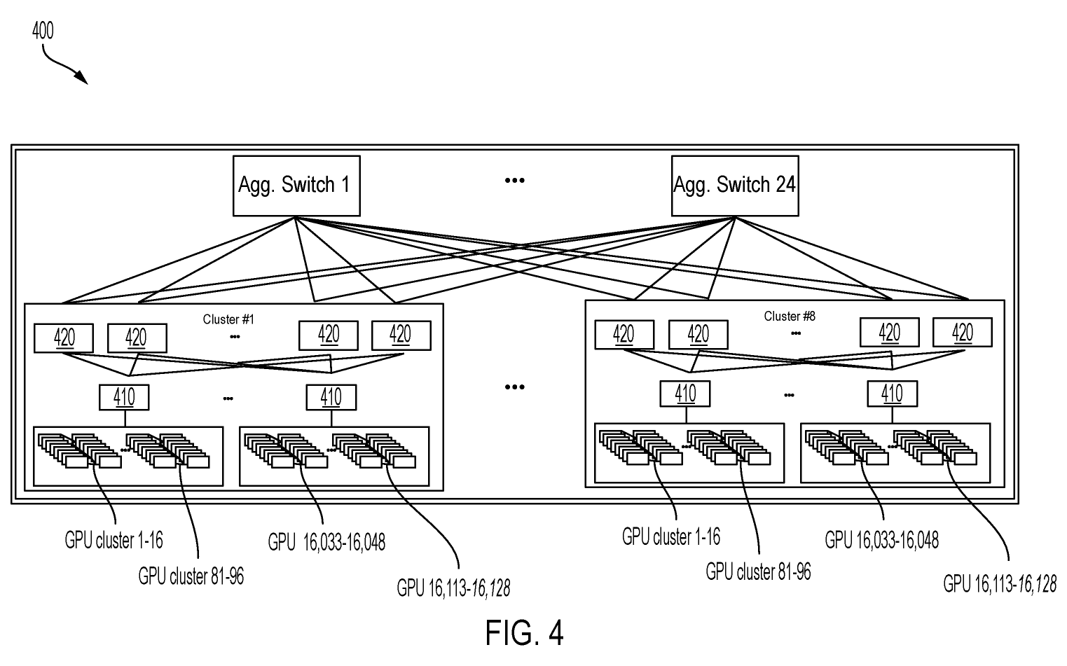

FIG. 4 illustrates multiple optoelectrical crossbar switches (labeled “Agg. Switch,” a first switch layer 410, and/or a second switch layer 420 in FIG. 4) arranged in an architecture 400 to support training operations in a system. As illustrated, the optoelectrical crossbar switches may be layered, such that a large number of xPUs may be connected and/or utilized in tandem to perform various training workloads. For example, the first switch layer 410 and the second switch layer 420 may be two layers within a cluster (as illustrated) and may be layered under the Agg. Switches in the architecture 400. The number of xPUs per cluster may vary based on the connections and bandwidth between the xPUs and/or the optoelectrical crossbar switches, and the number of clusters may vary based on the number of optoelectrical crossbar switches used to connect the clusters. Further, although illustrated as three levels of switches, more levels (or hops) may be added by adding more optoelectrical crossbar switches while monitoring the latency between the xPUs to ensure a threshold latency may be satisfied. For example, a number of levels in a system may be four, five, six, or more, facilitated by the optoelectrical crossbar switches, so long as the latency threshold is satisfied in the system design. In such examples, it may be possible to support architectures where one million or more xPUs may be implemented, where varying levels of oversubscription may be utilized to accommodate the various number of links between the levels of the optoelectrical crossbar switches. For example, as illustrated in FIG. 4, a 7:1 oversubscription may be implemented within a system including multiple optoelectrical crossbar switches.

A traditional training system utilizing traditional packet-based switches may be arranged such that each cluster may have about 4000 xPUs and where the latency in the system may be greater than four µs. In instances in which the optoelectrical crossbar switches are implemented, more than 16,000 xPUs may be included in the system distributed across eight clusters, where the latency may be less than one µs. The increase in the number of xPUs and/or the reduction in the latency in the system with the optoelectrical crossbar switches may be attributed to the number of links supported by the optoelectrical crossbar switches, where each optoelectrical crossbar switch may support approximately 768 links at 200 Gbps (or 192 links at 800 Gbps). In some instances, the number of xPUs included in a system utilizing the optoelectrical crossbar switches may be scaled to 130,000 xPUs or more with a minimum 800 Gbps bandwidth while using 30% or fewer switches relative to a system implemented using traditional packet-based switches at 400 Gbps. If designing a system using 400 Gbps minimum bandwidth and the optoelectrical crossbar switch, greater than 500000 xPUs may be interconnected, which may be an approximate 5 times increase from a 100k system using packet-based switches or a 125 times improvement with equivalent latency, while only increasing the number of switches by 30% in the system. These are just some examples and not limitations on how an end user might deploy the technology of the present disclosure.

The optoelectrical crossbar switches may support up to 192 links per unit with an assumption that the links may include 4 x 200 Gbps lanes in any direction, such that each link may support 800 Gbps transmissions. However, the links can be anywhere from a single lane of 200 Gbps for 768 links, or more lanes per link for fewer links. As the crossbar switch scales, so can both the number of lanes, number of links, and/or the number of lanes per link. In an example, a cluster of eight xPUs using an optoelectrical crossbar switch may have any length (e.g., up to about 500m) link length so long as the link length satisfies an allowable latency (where typical latency is calculated at approximately 5 ns/meter). In such situation, a 200m roundtrip link length would result in less than 1 µs of latency. Continuing the example, the eight xPUs may be packaged in a single box or rack such that the latency may be less than 5 ns (e.g., less than 1m), and the system may scale from 8 xPUs to 96 xPUs by including multiple boxes in a server rack (where the multiple boxes in the server rack may be within 3m of each other, or approximately 15 ns of latency), such that the scaled up xPUs (e.g., the 96 xPUs) may maintain better than 500 ns latency even through a crossbar switch with associated buffering and latency that may be required.

As illustrated in FIG. 4, each xPU may have 16 links, where each link may support 800 Gbps in each direction. Further, each xPU may include a number of optical engines (e.g., having a total of 64 lanes, but arranged as 4 lanes per link which is the 16 links). In such arrangement, the 16 links of the xPUs may facilitate connections to 15 other xPUs in the cluster and one extra link that may be used to connect to the optoelectrical crossbar switch for the cluster. In an alternate configuration where only 400 Gbps (2 lanes) may be used per link, then the system can have a total of 32 links per xPU and the rack configuration can increase to 192 xPUs.

A system using a traditional packet-based switch may support up to about 72 xPUs and a latency of approximately 1 µs at 400 Gbps. In comparison, a system implementing the optoelectrical crossbar switch described herein may support up to 16,000 xPUs at 800 Gbps, or 64,000 xPUs at 400 Gbps, while maintaining one µs latency, assuming less than a 100m roundtrip distance is achieved, resulting in more densely packed xPUs in the system, which may improve a training capability of the system. In instances in which more hops (e.g., levels of switches) are implemented, such as via clusters, the latency may increase due to time of flight while significantly increasing the number of connected xPUs. For example, adding three levels of switches, as illustrated in FIG. 4, may increase the latency to three µs (e.g., one µs of latency for each level) while facilitating support of up to nearly 130,000 xPUs (e.g., approximately 129,029 xPUs) at 800 Gbps minimum bandwidth. Alternatively, or additionally, if 400 Gbps bandwidth is maintained, it may be possible to achieve 516,096 xPUs interconnected.

In an example, a traditional packet-based switch that may support 500 ns latency may utilize approximately 8 GPUs, whereas a system implementing the optoelectrical crossbar switch described herein and maintaining a similar latency may support approximately 96 GPUs. In another example, a traditional packet-based switch that may support 1 µs latency may utilize approximately 72 GPUs, whereas a system implementing the optoelectrical crossbar switch described herein and maintaining a similar latency may support approximately 16,128 GPUs. In another example, a traditional packet-based switch that may support 1 µs latency may utilize approximately 4000 GPUs, whereas a system implementing the optoelectrical crossbar switch described herein and maintaining a similar latency may support approximately 129,029 GPUs.

In some instances, the system of connected xPUs, via the optoelectrical crossbar switches, may be composable based on the fiber connections between the xPUs and/or the optoelectrical crossbar switches. In some instances, the optoelectrical crossbar switches and/or the optical engines may be reconfigured based on whether the system is to perform a training workload or an inference workload. In these and other instances, the system of optoelectrical crossbar switches and/or optical engines may be reconfigured using software in association with the optoelectrical crossbar switches and optical engines, without changes to the architecture 400, where the optical engines may be physically reconfigured as described herein. For example, in a training solution, 16 xPUs may be directly connected to one another and to a common optoelectrical crossbar switch, and again to a higher-level optoelectrical crossbar switch. In an inference solution, the xPUs may be directly connected to each switch included in the system (such that the system is one layer). In such examples, the system may be reconfigured by connecting the optical fibers associated with the optoelectrical crossbar switches and/or xPUs, such that the architecture 400 of the system may be unchanged, only connection points between the components (e.g., the optoelectrical crossbar switches and/or the optical engines) in the system may be changed. For example, to repurpose a system from the inference solution to the training solution, it is possible in this composable architecture 400 to repurpose existing xPUs rather than having to purchase additional separate hardware thus enabling significant flexibility to the hardware and system design.

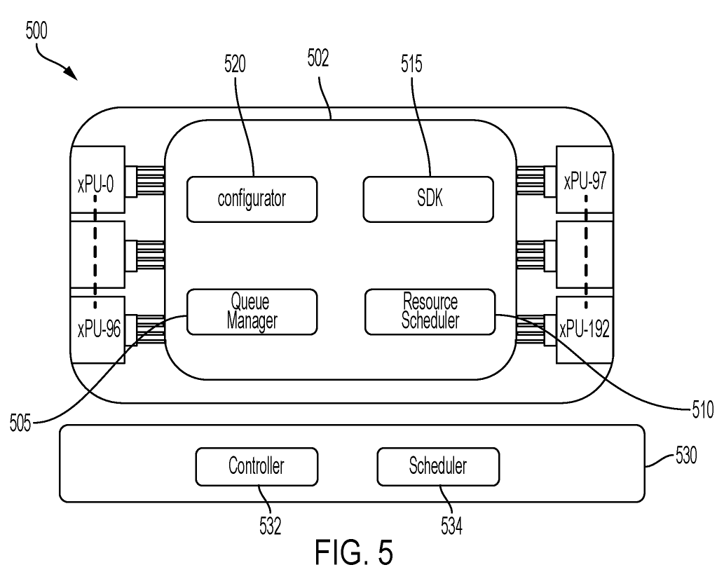

FIG. 5 illustrates an example software and control device 500 (which may be referred to as “the device 500”) that may be used to control operations associated with a system of optoelectrical crossbar switches and/or optical engines. The device 500 may include software that may be operable to program, schedule, control, report, provide diagnostics and telemetry, performance metrics, test modes to and from the device 500 and/or perform operations in conjunction with the device 500. As described herein, the device 500 may be enabled in hardware and may be operable to reconfigure, manage, provide telemetry, predictability, and/or create a composable network of ASICs that may be interconnected with the optoelectrical package. Alternatively, or additionally, the device 500 may be operable to optimize the number of ASICs that may be interconnected with the optoelectrical package. In some instances, the software 502 associated with the optoelectrical crossbar switch may include a queue manager 505, a resource scheduler 510, a software development kit 515, and a configurator 520.

A separate control device 530 may be used to communicate to the software 502 associated with the optoelectrical crossbar switch, where the control device 530 may include a controller 532 and/or a scheduler 534. In some instances, the control device 530 may be referred to as a control plane. Alternatively, or additionally, the control device 530 may utilize a container orchestration platform (which may be open-source) that may contribute to automating deployment, scaling, and/or management of containerized applications. The queue manager 505 may be operable to manage requests or data flow. A resource scheduler 510 may identify available resources, such as xPUs, that may exist within the cluster and may be assigned to a next workload. A software development kit 515 may be used to enable programmability of an optical engine. A configurator 520 may specify pre-defined configurations of the resources that might be called upon to execute a workload. The control device 530 may control software updates and/or communication with the optoelectrical crossbar switch and a management interface as well as potentially enabling the scheduler functionality.

In some instances, it may be desirable and/or beneficial to separate workloads performed by a system of optoelectrical crossbar switches and/or optical engines by a cluster, as described herein. For example, a first cluster may deploy a first model, a second cluster may deploy a second model, and so forth. In such instances, the device 500 may configure the system such that each cluster is operable to perform a particular workload independent of other clusters, such as by causing the links in the cluster (e.g., the links associated with each xPU included in the cluster) to feed back to xPUs within their associated cluster rather than connecting to other xPUs in other clusters (such as via additional optoelectrical crossbar switches). In this way, 192 xPUs connected via the optoelectrical crossbar switch can be configured into subsets, or sub-clusters, of 2, 3, 4, etc., up to 192 xPUs and there can be multiple subsets within the 192 xPUs running different models simultaneously. As soon as a sub-cluster completes a workload associated with a model, the xPUs in the sub-cluster can be redeployed to another model and/or may be interconnected with other available xPUs as controlled and defined by the device 500.

Further, the device 500 may be operable to reconfigure the system based on changes to the workload assigned to the system. For example, as a number of models to be deployed increase or decrease, the number of clusters and/or xPUs may increase or decrease accordingly. In another example, in instances in which the system is to change from performing training workloads to inference workloads, the device 500 may reconfigure connections between the optoelectrical crossbar switches and/or the optical engines. In these and other embodiments, the reconfigurations may be performed without disturbing operational workloads. For example, in instances in which a first model is deployed in a first cluster, the remaining cluster(s) may be reconfigured without a disruption to the first model in the first cluster.

In an example, during inference, ten different users may want to run an inference workload, where each workload may utilize a different number of xPUs in the system. The device 500 may configure the optoelectrical crossbar switches based on the number of xPUs needed per workload. In some instances, the xPUs may be able to communicate at a full 12.8 Tb/s of bandwidth if only two xPUs are connected, such that no additional xPUs may be necessary. In another instance, an “all to all” arrangement may also be configured where each xPU in the system may be operable to communicate with every other xPU in the system, and where all of the communications between the xPUs may be at 800 Gbps.

In another example, a first user may request a number of xPUs (e.g., that may be less than a total number of xPUs available in the system) to perform a workload and the device 500 may cause the optoelectrical crossbar switch to be reconfigured. During the performance of the workload, a second user may request a second number of xPUs to perform a second workload and the device 500 may cause the optoelectrical crossbar switch to again reconfigure, where the reconfiguration for the second workload may not cause an interruption to the operations associated with the first workload.

In another example, in instances in which a particular xPU may be degraded or cease operations, the device 500 may cause a reconfiguration of the system to avoid the particular xPU without causing disruptions to other workloads being performed by the system.

In another example, a private workload (e.g., a workload that may include sensitive information) may be isolated from other workloads by isolating the xPUs and/or clusters to perform the private workload. For example, a first cluster may be isolated from other clusters such that the first cluster may perform the private workload without data leakage from the first cluster to the other clusters as might happen in some shared workload configurations.

In some instances, the device 500 may be operable to reconfigure the system and/or the components in the system (e.g., the optoelectrical crossbar switches and/or the optical engines) to facilitate virtualization operations. For example, a first portion of the xPUs (which may be a cluster, or a smaller or larger portion than a cluster) may be reserved and/or reconfigured to support a virtual environment and/or workloads in a virtual environment without disruption of workloads being performed by other xPUs and/or clusters in the system.

Terms used in the present disclosure and especially in the appended claims (e.g., bodies of the appended claims) are generally intended as “open terms” (e.g., the term “including” should be interpreted as “including, but not limited to.”).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is expressly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase preceding two or more alternative terms, whether in the description, claims, or drawings, should be understood to contemplate the possibilities of including one of the terms, either of the terms, or both of the terms. For example, the phrase “A or B” should be understood to include the possibilities of “A” or “B” or “A and B.”

All examples and conditional language recited in the present disclosure are intended for pedagogical objects to aid the reader in understanding the present disclosure and the concepts contributed by the inventor to furthering the art, and are to be construed as being without limitation to such specifically recited examples and conditions. Although implementations of the present disclosure have been described in detail, various changes, substitutions, and alterations could be made hereto without departing from the spirit and scope of the present disclosure.

What is claimed is:

1. An optoelectrical package, comprising:
at least one electrical application-specific integrated circuit (ASIC) disposed at a central portion of a communication interface, wherein the electrical ASIC incorporates a crossbar functionality;
at least one optical engine arranged relative to the communication interface, electrically connected to the at least one electrical ASIC, and disposed adjacent to the at least one electrical ASIC, further comprising:
a fiber connector for one or more fibers;
a photonic integrated circuit; and
an electronic integrated circuit,
wherein the at least one optical engine is configured to convert an optical signal obtained from the fiber connector to an electrical signal for use by the at least one electrical ASIC and vice versa.

2. The optoelectrical package of claim 1, wherein the communication interface is an interposer or a substrate.

3. The optoelectrical package of claim 2, wherein the at least one optical engine is disposed on the substrate and electrically connected via the substrate.

4. The optoelectrical package of claim 2, wherein the at least one optical engine is disposed on the interposer.

5. The optoelectrical package of claim 2, wherein the interposer is common between the at least one optical engine and the at least one electrical ASIC.

6. The optoelectrical package of claim 5, wherein the interposer, the at least one optical engine, and the at least one electrical ASIC are packaged using Chip-on-Wafer-on-Substrate technology.

7. The optoelectrical package of claim 2, wherein:
the at least one optical engine is integrated into the optoelectrical package by embedding into the interposer; and
the at least one electrical ASIC sits atop the interposer.

8. The optoelectrical package of claim 7, wherein the at least one optical engine replaces a silicon bridge within the interposer.

9. The optoelectrical package of claim 1, wherein the at least one optical engine is enabled with the crossbar functionality.

10. The optoelectrical package of claim 9, wherein the electronic integrated circuit is enabled with the crossbar functionality in the at least one optical engine.

11. The optoelectrical package of claim 9, wherein the photonic integrated circuit is enabled with the crossbar functionality in the at least one optical engine.

12. The optoelectrical package of claim 1, wherein:
the at least one electrical ASIC is an xPU, a memory, or any other ASIC other than a crossbar switch; and
the at least one optical engine contains the crossbar functionality enabled in the electronic integrated circuit.

13. The optoelectrical package of claim 12, wherein the at least one optical engine contains the crossbar functionality enabled in the photonic integrated circuit.

14. The optoelectrical package of claim 1, wherein a software and control device enabled in hardware is operable to reconfigure and create a composable network of ASICs interconnected with the optoelectrical package.

15. The optoelectrical package of claim 1, wherein an optoelectrical crossbar switch is enabled with more than 512 lanes at greater than 100 Gbps bandwidth per lane.

16. The optoelectrical package of claim 1, wherein an optoelectrical crossbar switch is enabled with less than 500ns latency.

17. The optoelectrical package of claim 1, wherein the at least one optical engine comprises networking protocol translation.

18. The optoelectrical package of claim 17, wherein the networking protocol translation is enabled in the electronic integrated circuit.

19. The optoelectrical package of claim 1, wherein communication between the at least one electrical ASIC and the at least one optical engine is enabled through die-to-die (D2D) connectivity.

20. An optoelectrical package, comprising:
at least one electrical application-specific integrated circuits (ASIC) disposed at a central portion of an interposer, wherein the electrical ASIC incorporates a crossbar functionality;
at least one optical engine integrated into the interposer, electrically connected to the at least one electrical ASIC, and disposed adjacent to the at least one electrical ASIC, further comprising:
a fiber connector for one or more fibers;
a photonic integrated circuit; and
an electronic integrated circuit,
wherein the at least one optical engine is configured to convert an optical signal obtained from the fiber connector to an electrical signal for use by the at least one electrical ASIC and vice versa.
